(19) United States
(12) Patent Application Publication
(10) Pub. No.: US 2014/0103351 A1
(43) Pub. Date: Apr. 17, 2014

(54) Low Temperature Poly-Silicon Thin Film Transistor, Manufacturing Method thereof, and Display Device

(71) Applicant: InnoLux Corporation, Miao-Li County (TW)

(72) Inventors: Yu-Tsung LIU, Miao-Li County (TW); Te-Yu LEE, Miao-Li County (TW); Chien-Ta HUANG, Miao-Li County (TW)

(73) Assignee: InnoLux Corporation, Miao-Li County (TW)

(21) Appl. No.: 14/047,164

(22) Filed: Oct. 7, 2013

(30) Foreign Application Priority Data
Oct. 15, 2012 (TW) 101137900

(51) Int. Cl. H01L 29/786; H01L 29/66

(52) U.S. Cl. CPC H01L 29/78678; H01L 29/66765
USPC 257/72; 438/158

(57) ABSTRACT

The present invention discloses a low temperature poly-silicon thin film transistor, a manufacturing method thereof, and a display device. Particularly, a metal film is formed between source and drain electrodes and a first conductive layer, and the metal film reacts with the poly-silicon of the source and drain electrodes to form metal silicide, whereby activating the source and drain electrodes at a low temperature. As such, the temperature of the manufacturing process of low temperature poly-silicon thin film transistor can be confined to 350° C. or lower.

### CROSS REFERENCE TO RELATED APPLICATION

This application claims the benefits of the Taiwan Patent Application Serial Number 101137900, filed on Oct. 15, 2012, the subject matter of which is incorporated herein by reference.

### BACKGROUND OF THE INVENTION

1. Field of the Invention

The present invention relates to a low temperature poly-silicon thin film transistor, a manufacturing method thereof, and a display device, and particularly to a method for manufacturing a low temperature poly-silicon thin film transistor which can reduce the number of annealing processes and the process temperature.

2. Description of Related Art

Nowadays, flat panel displays using liquid crystal displays (LCDs) have become the mainstream product on the market due to its advantages of energy saving, low radiation, and lightweight. The thin film transistors in the liquid crystal displays are classified into two types: one made of amorphous-silicon (a-Si), and the other made of poly-silicon (p-Si). The current trend for manufacturing thin film transistor is by an amorphous-silicon process, and the related techniques thereof are more mature. However, since poly-silicon has a carrier mobility at least 100 times of that of amorphous-silicon, and has advantages of high brightness, high resolution, low power, and being light and thin, the manufacturing of the poly-silicon liquid crystal display has been extensively studied.

In the poly-silicon liquid crystal display technology, the low temperature poly-silicon (LTPS) technology is the new generation of manufacturing technology. The display made by the low temperature poly-silicon process is much slimmer by scaling down the components. In addition, more electronic circuits can be integrated therein, and therefore the size of the low temperature poly-silicon thin film transistor can be minimized. Since the products manufactured by the LTPS technology have advantages of lightweight and low manufacturing cost, this technology has attracted much attention on the market of liquid crystal display.

However, the conventional manufacturing process for low temperature poly-silicon thin film transistor includes hydrogenation, dehydrogenation, and dopant activation processes which necessitate further heat or laser treatment. The dopant activation process is to activate the doped impurity to lower the resistance of the poly-silicon layer of the source and drain electrodes and increase the off-state voltage. However, the cost of the laser activation process is high, while the high temperature process limits the choice of substrate material, which in turn, limits the applications of the low temperature poly-silicon thin film transistor. Therefore, what is needed in the art is to provide a method for manufacturing a low temperature poly-silicon thin film transistor, in which the laser activation and the high temperature process can be omitted, to save cost and broaden the applications of the low temperature poly-silicon thin-film transistor.

### SUMMARY OF THE INVENTION

An object of the present invention is to provide a low temperature poly-silicon thin film transistor, a manufacturing method thereof, and a display device containing the same. Instead of activating doped source and drain electrodes by laser activation held in the conventional process, the present invention is characterized by forming a metal film between a first conductive layer and source and drain electrodes to lower the activation temperature of the source and drain electrodes, wherein the metal film is selected from the group consisting of aluminum, nickel, titanium, cobalt, and tungsten, and a metal silicide layer is formed by a reaction between the source and drain electrodes and the metal film. As such, not only the cost for laser process may be saved, but also the temperature of the overall manufacturing process can be most preferably limited to 350° C. or lower. Accordingly, since the temperature of the overall manufacturing process is reduced, more types of substrate materials are suitable for various manufacturing process of the display in the future.

The method for manufacturing a low temperature poly-silicon thin film transistor according to the present invention comprises the following steps: (A) providing a low temperature poly-silicon thin film transistor substrate having: a substrate; a buffer layer formed on the substrate; a poly-silicon layer formed on the buffer layer, wherein the poly-silicon layer has a source electrode, a drain electrode, and a channel; a first insulator partially formed on the poly-silicon layer, wherein the source electrode and the drain electrode of the poly-silicon layer are exposed therefrom; a gate electrode partially formed on the first insulator; a second insulator partially formed on the gate electrode and partially formed on the first insulator; (B) forming a metal film on the exposed source electrode and drain electrode of the low temperature poly-silicon thin film transistor substrate; (C) forming a first conductive layer on the metal film, wherein the first conductive layer protrudes above the second insulator, and performing an annealing process while activating a doping substance in the metal film so that the metal film reacts with the source electrode and the drain electrode to form a metal silicide layer; and (D) forming a protective layer on the first conductive layer and the second insulator to planarize topography of the low temperature poly-silicon thin film transistor

In the step (A), the poly-silicon layer preferably has a thickness of 30 nm-100 nm and is formed from an amorphous-silicon (a-Si) layer poly-crystallized by laser annealing. The buffer layer preferably has a thickness of 100 nm-400 nm and a material thereof is at least one selected from the group consisting of silicon oxide and silicon nitride. In addition, the first insulator preferably has a thickness of 40 nm-300 nm and is at least one selected from the group consisting of a silicon oxide layer and a silicon nitride layer. The gate electrode is made of molybdenum, tungsten or an alloy thereof, and preferably molybdenum.

Furthermore, in the step (B), a material of the metal film is at least one selected from the group consisting of aluminum, nickel, titanium, cobalt, and tungsten, and preferably nickel. The metal film is formed by sputtering a metal film onto the source electrode and the drain electrode to a thickness of about several tens to hundreds of nanometers. In the step (C), the first conductive layer is composed of molybdenum, molybdenum/aluminum/molybdenum, or titanium/aluminum/titanium, and a minimum distance (Dₘᵢₙ) between the metal silicide layer at the source electrode and the metal silicide layer at the drain electrode is 2 μm or more.

The present invention also provides a display device, comprising a low temperature poly-silicon thin film transistor substrate, wherein the low temperature poly-silicon thin film transistor substrate comprises: a substrate; a buffer layer formed on the substrate; a poly-silicon layer formed on the buffer layer, wherein the poly-silicon layer has a source electrode, a drain electrode, and a channel, and the source electrode, the drain electrode, and the channel are doped; a first insulator partially formed on the poly-silicon layer; a gate electrode patterned and formed on the first insulator, wherein the gate electrode corresponds to the channel; a second insulator formed on the gate electrode and the first insulator; vias passing through the second insulator and the first insulator over the source electrode and the drain electrode respectively; a metal film formed on the vias over the source electrode and the drain electrode; a first conductive layer formed on the metal film, wherein the first conductive layer protrudes above the second insulator, wherein a metal silicide layer is disposed between the metal film and the source electrode and the drain electrode of the poly-silicon layer; and a protective layer formed on the first conductive layer and the second insulator.

In the above-mentioned display device, the substrate for the low temperature poly-silicon thin film transistor is a glass substrate or a plastic substrate, and the metal silicide layer is formed by a reaction between at least one selected from the group consisting of aluminum, nickel, titanium, cobalt, and tungsten and the source and drain electrodes. In addition, a minimum distance (Dₘᵢₙ) between the metal silicide layer at the source electrode and the metal silicide layer at the drain electrode is required to be 2 μm or more.

According to the present invention, the metal silicide layer between the source electrode and the drain electrode and the metal film is formed by a reaction between at least one selected from the group consisting of aluminum, nickel, titanium, cobalt, and tungsten with the poly-silicon layers of source electrode and the drain electrode, and a minimum distance (Dₘᵢₙ) between the metal silicide layer of the source electrode and the metal silicide layer of the drain electrode is 2 μm or more. Further, the first conductive layer is consisted of molybdenum, molybdenum/aluminum/molybdenum, or titanium/aluminum/titanium.

The metal film between the source electrode and the drain electrode can react with the poly-silicon of the source electrode and the drain electrode in the annealing process to form a metal silicide which is distributed in the heavily doped poly-silicon layer or diffused to the lightly doped poly-silicon layer, but not to the channel region of poly-silicon. However, the distance between the metal silicide can be controlled by regulating the annealing temperature and time to prevent the metal silicide from diffusing to the channel region. For example, the annealing process may be performed at 330° C. for 1-2 hours. In addition, the distance between the metal silicide at the source electrode and the drain electrode on the opposite sides of the channel should be controlled at 2 to 3 μm in order to maintain the operation function of the channel. The metal silicide may reduce the activation energy required for activating the doping substance in the source electrode and the drain electrode, and thereby the activation temperature can be decreased. Such a decrease in the temperature of the manufacturing process of low temperature poly-silicon thin film transistor is an important advance in the manufacturing process of low temperature poly-silicon thin film transistor.

### BRIEF DESCRIPTION OF THE DRAWINGS

FIGS. 1A-1O show the flow chart for manufacturing the low temperature poly-silicon thin film transistor according to the present invention.

FIGS. 2A and 2B show aspects of the metal silicide layer according to the present invention.

### DETAILED DESCRIPTION OF THE PREFERRED EMBODIMENT

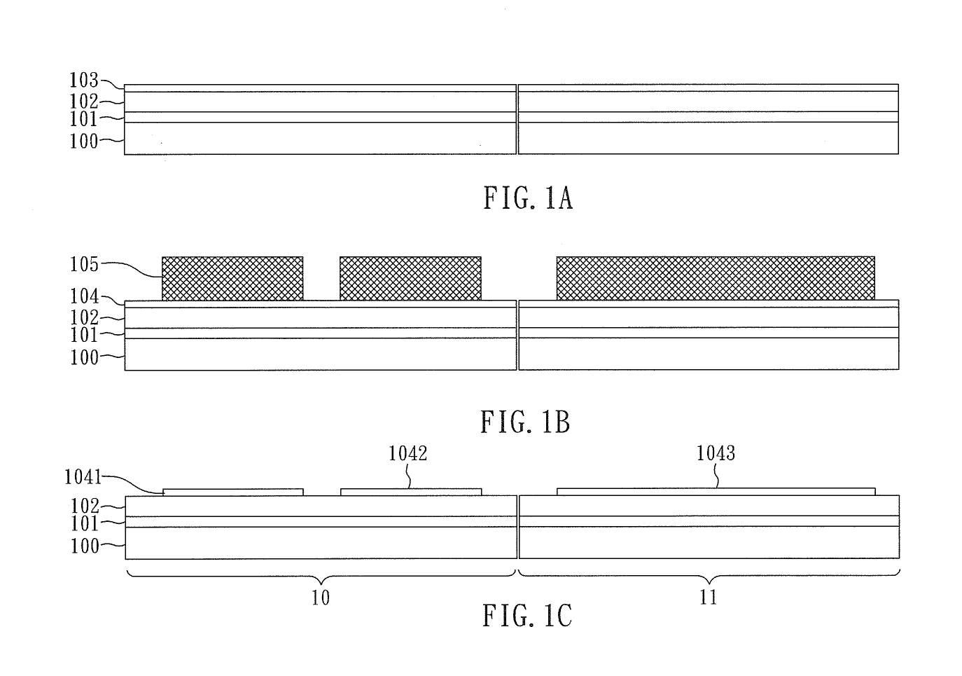

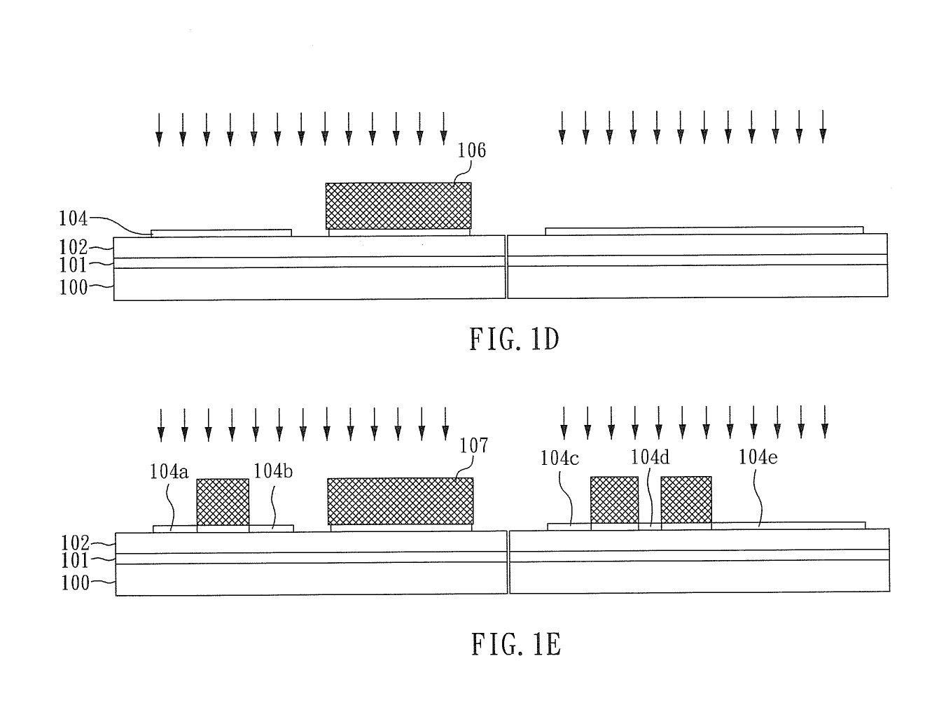

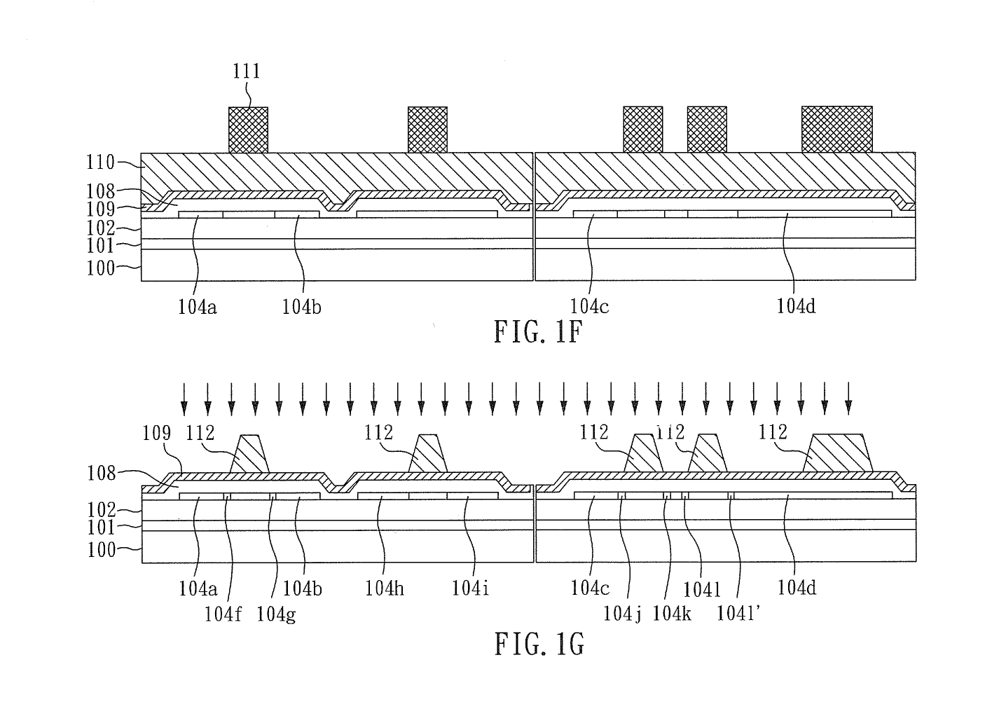

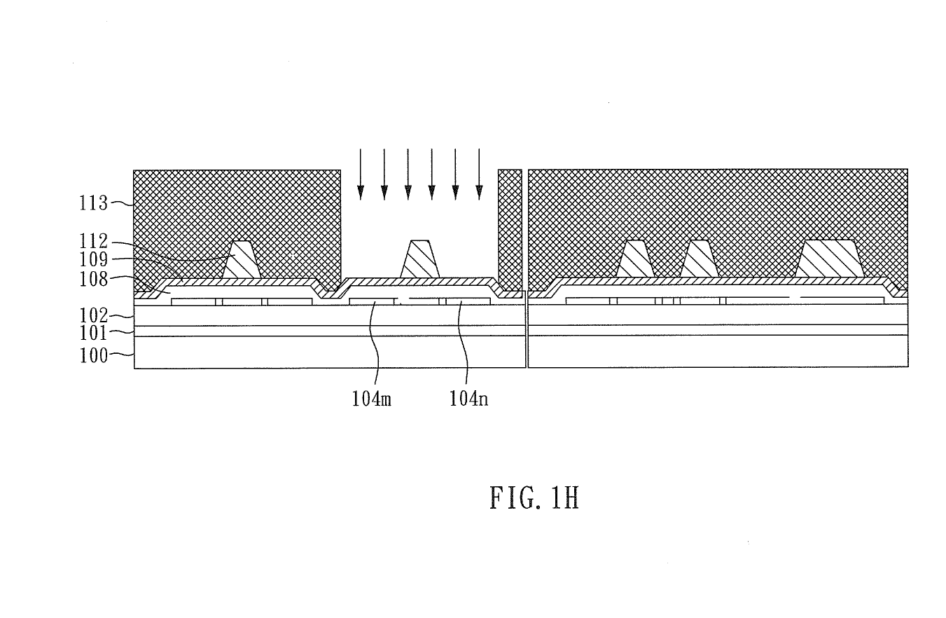

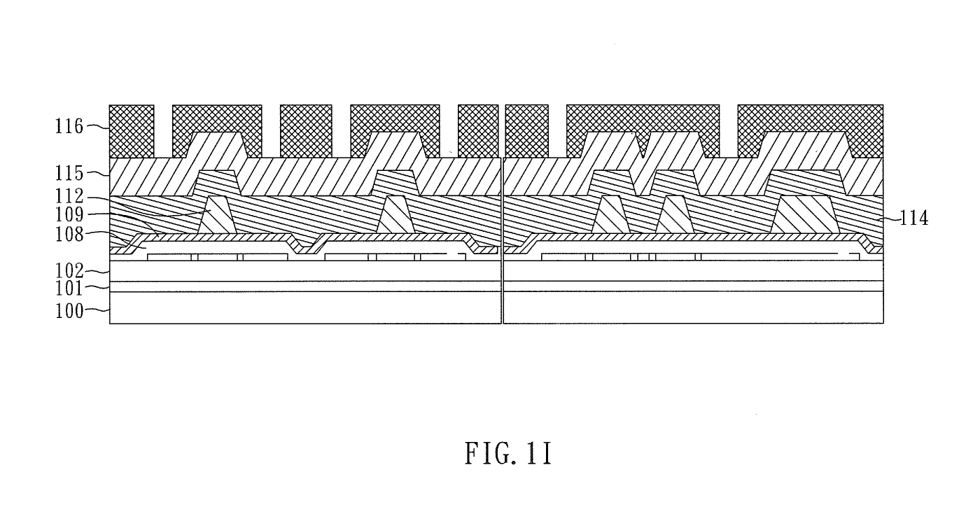

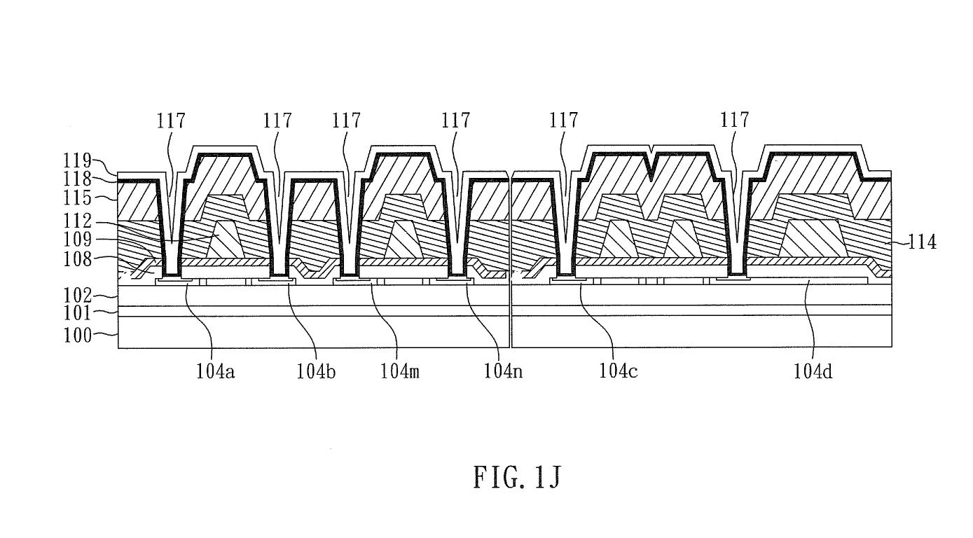

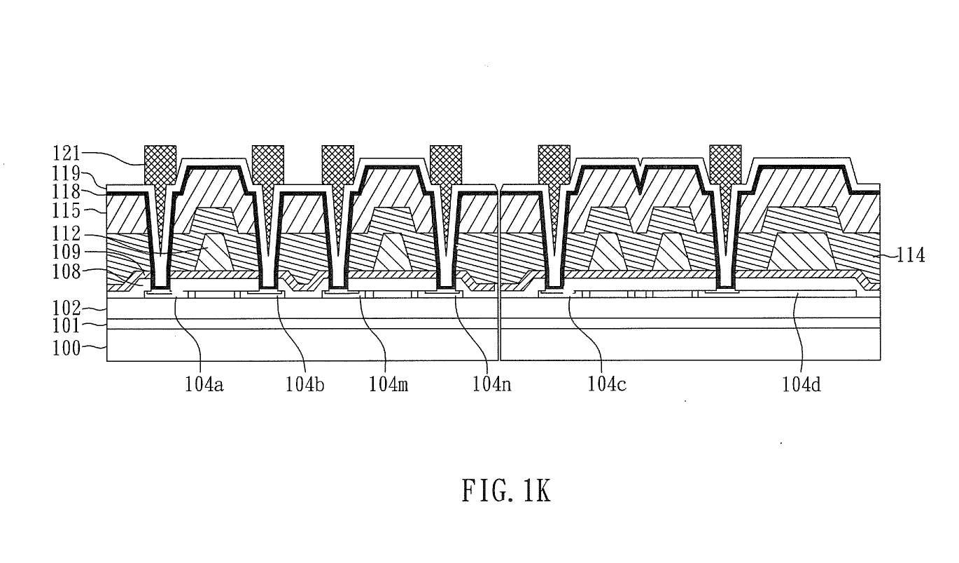

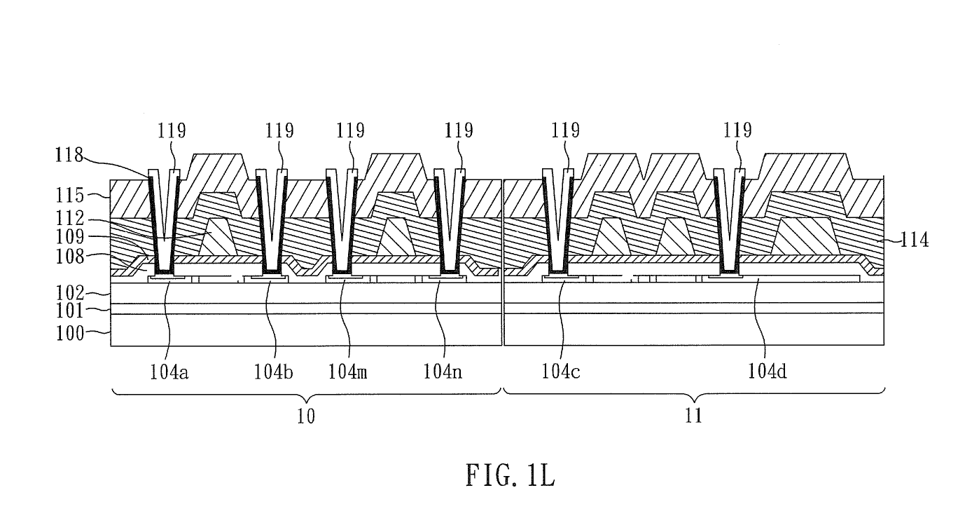

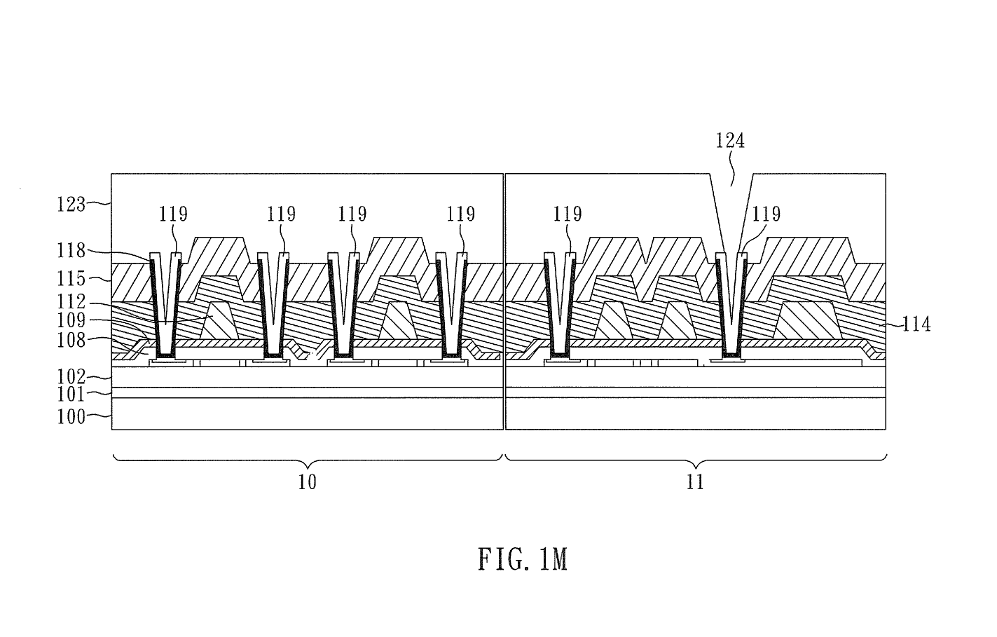

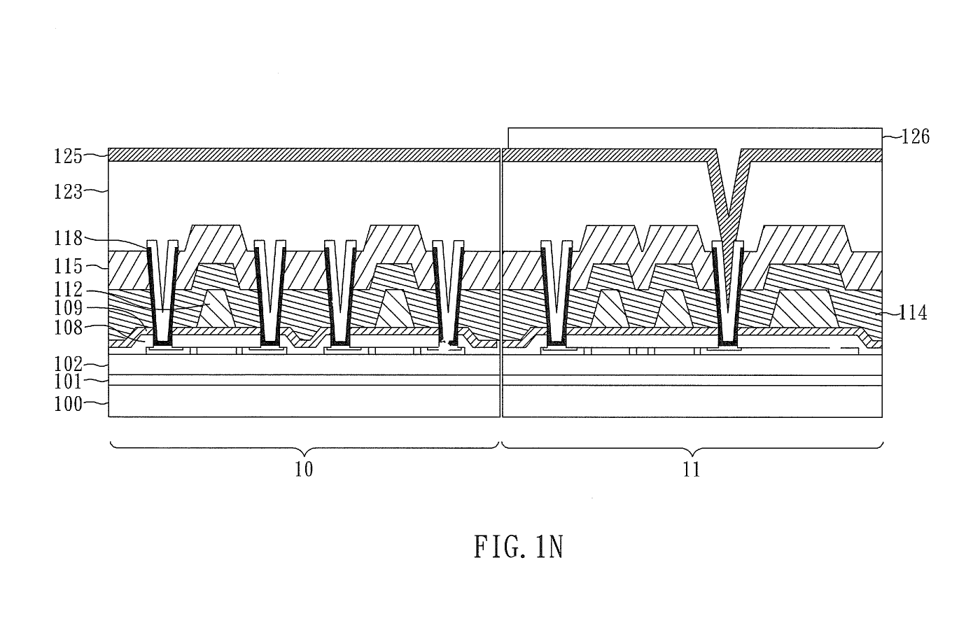

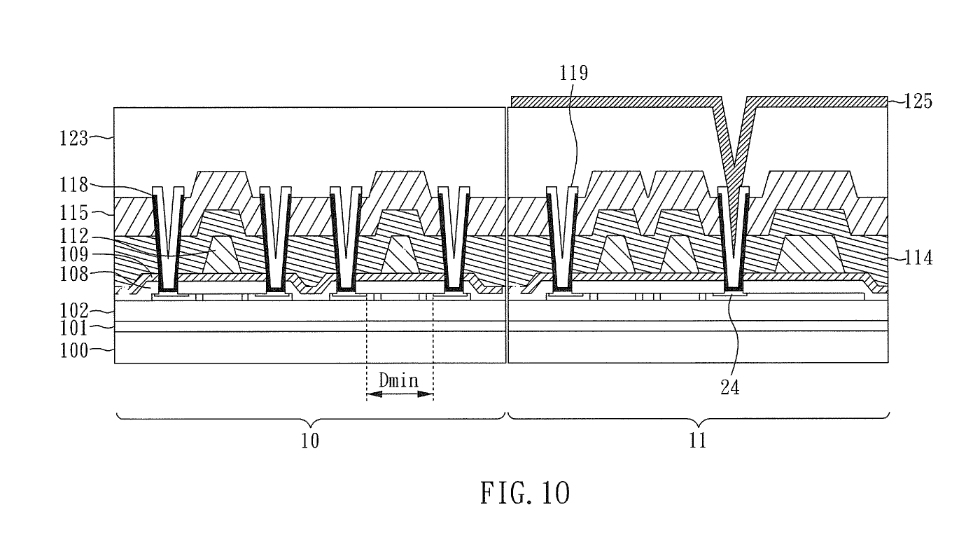

A low temperature poly-silicon thin film transistor according to a preferred embodiment of the present invention is shown in FIG. 1O, and a preferred manufacturing process thereof is shown in FIGS. 1A-1O.

FIG. 1M shows the structure of the low temperature poly-silicon thin film transistor according to the present invention, which includes a control area and a pixel area, wherein the control area includes an NMOS transistor area and a PMOS transistor area, and the pixel area includes an NMOS transistor area. The manufacturing method thereof is described as follows.

First, as shown in FIG. 1A, a substrate is provided, and the substrate comprises: a substrate 100; a silicon nitride buffer layer 101 formed on the substrate 101; and a silicon oxide buffer layer 102 formed on the silicon nitride buffer layer 101. An amorphous-silicon (a-Si) layer 103 is formed on the substrate, and the amorphous-silicon (a-Si) layer 103 has a thickness of about 30 nm-100 nm. The amorphous-silicon (a-Si) layer 103 is converted into a poly-silicon layer 104 by laser annealing. Next, as shown in FIG. 1B, a first photoresist 105 is formed on the poly-silicon layer 104. After photolithography and etching processes, the poly-silicon layer 104 is etched, and the first photoresist 105 is removed by a chemical solvent to obtain a structure as shown in FIG. 1C, wherein the left region of the poly-silicon layer serves as an NMOS transistor area 1041 and a PMOS transistor area 1042 of a control area 10, while the right region of the poly-silicon layer servers as an NMOS transistor area 1043 of a pixel area 11.

Then, as shown in FIG. 1D, a second photoresist 106 is formed in the PMOS transistor area 1042 of a control area 10, and a channel doping is performed by doping boron into the substrate, in which the doping dose of boron is about 1E11-1E12. As shown in FIG. 1E, a third photoresist 107 is formed in the NMOS transistor area 1041 of the control area 10 and the NMOS transistor area 1043 of the pixel area 11, and the exposed poly-silicon layer is implanted with phosphorus dopant having a heavy dose of about 1E14-1E15, to form source electrodes 104a, 104c, and drain electrodes 104b, 104e in the NMOS transistor area 1041 of the control area 10 and the NMOS transistor area 1043 of the pixel area 11, and the third photoresist 107 is removed thereafter.

As shown in FIG. 1F, after a first silicon oxide insulator 108 and a first silicon nitride insulator 109 are formed on the poly-silicon layer and the silicon oxide buffer layer 102, a gate electrode conductive layer 110 is formed on the first silicon nitride insulator 109, wherein the gate conductive layer 110 may be made of molybdenum. The gate conductive layer 110 is patterned into a gate electrode 112 by a third photoresist 111 formed thereon using lithography and etching processes, as shown in FIG. 1G. Next, the gate electrode 112 is used as a mask to implant phosphorus with a light doping dose of about 1E12-1E14, thereby forming a lightly doped area 104f, 104g, 104h, 104i, 104j, 104k, 104l, and 104l′. Then, as shown in FIG. 1H, a fourth photoresist 113 is formed on the NMOS transistor area 1041 of the control area 10 and the NMOS transistor area 1043 of the pixel area 11, while the PMOS transistor area 1042 of the control area 10 is exposed and doped with boron having a heavy dose of about 1E14-1E15, to form a source electrode 104m and a drain electrode 104n in the PMOS transistor area 1042 of the control area 10.

Next, as shown in FIG. 1I, the fourth photoresist 113 is removed, and then a second silicon nitride insulator 114 with a thickness of hundreds of nanometers is formed on the gate electrode 112 and the first silicon nitride insulator 109. Then, a second silicon oxide insulator 115 with a thickness of hundreds of nanometers is formed on the second silicon nitride insulator 114, and a fifth photoresist 116 is formed on the second silicon oxide insulator 115. As shown in FIG. 1J, a plurality of vias 117 are formed using lithography and etching processes, to expose the source electrodes 104a, 104m, 104c and drain electrodes 104b, 104n, 104d of the NMOS transistor area 1041 of the control area 10, the PMOS transistor area 1042 of the control area 10, and the NMOS transistor area 1043 of the pixel area 11. Next, a nickel film 118 is formed on the exposed source electrodes (104a, 104m, 104c), drain electrodes (104b, 104n, 104d), and the vias 117, followed by depositing a first conductive layer 119 on the nickel film 118, wherein the first conductive layer 119 is formed by molybdenum/aluminum/molybdenum multilayer deposition.

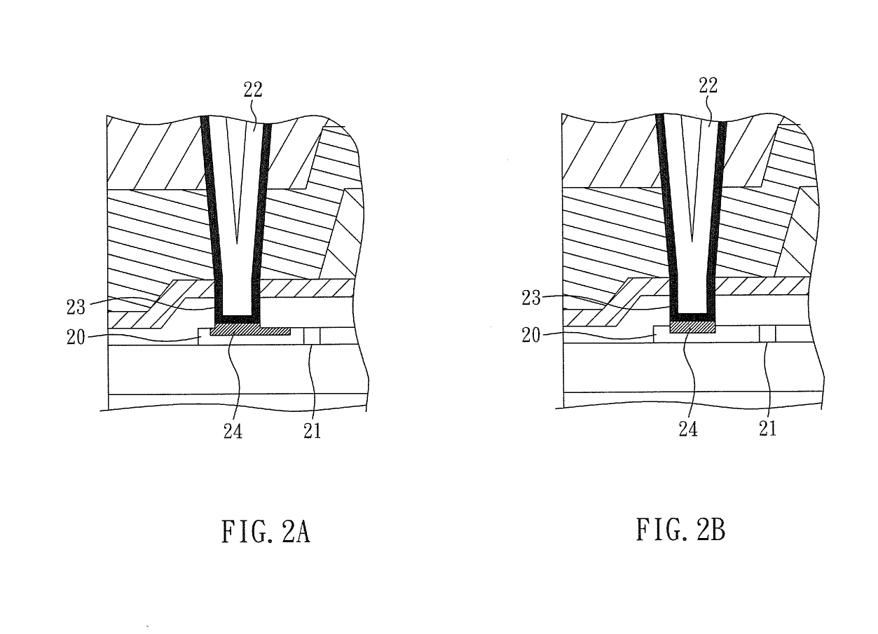

After the nickel film 118 and the first conductive layer 119 are deposited, an annealing process is performed. In the annealing process, the environment temperature is first raised to a predetermined temperature for annealing, and then rapidly cooled down to the ambient temperature, so that the dopants of the heavily doped region, the light doped region, and the channel region of the poly-silicon layer 20 can be activated. After the annealing process, the structure are shown in FIGS. 2A and 2B, which includes a first conductive layer 22, a nickel film 23, and a nickel silicide layer 24 formed by the reaction between the nickel metal film 23 and the source and drain electrodes in contact therewith. In addition, the annealing time is controlled so that the nickel silicide layer 24 can diffuse from the source and drain electrodes of the heavily doped poly-silicon layer 20 as well as the nickel film 23, and a minimum distance (Dₘᵢₙ) between the metal silicide layer at the source electrode and the metal silicide layer at the drain electrode is required to be 2-3 μm or more in order to maintain good transistor performance. Because of the presence of the nickel film 118, the activation temperature of the heavily doped region, the light doped region, and the channel region of the poly-silicon layer may be reduced.

TABLE 1
diffusion distance and annealing time of nickel silicide

| | | | Diffusion | Diffusion |
|---|---|---|---|---|
| | | Diffusion | distance | distance |
| Annealing | Material of | coefficient | within 1 hour | within 2 hour |
| temperature | active layer | (μm\hat{ }2/s) | (μm) | (μm) |
| 400° C. | a-Si | 1.9E−5 | 0.26 | 0.37 |
| | C—Si | 1.9E1 | 262.8 | 371.66 |
| | Poly-Si | 1.9E−2 | 8.31 | 11.75 |
| 350° C. | a-Si | 3.2E-6 | 0.11 | 0.15 |
| | C—Si | 3.2E0 | 107.08 | 151.43 |
| | Poly-Si | 3.2E−3 | 3.39 | 4.79 |
| 300° C. | a-Si | 3.9E−7 | 0.04 | 0.05 |
| | C—Si | 3.9E−1 | 37.3 | 52.75 |
| | Poly-Si | 3.9E−4 | 1018 | 1.67 |

Thereafter, as shown in FIG. 1K, a sixth photoresist 121 is formed on the first conductive layer 119, followed by patterning the first conductive layer 119 using lithography and etching processes, to form the first conductive layer 119 electrically connecting the source electrodes 104a, 104m, 104c and drain electrodes 104b, 104n, 104d of the control area 10 and the pixel area 11, as shown in FIG. 1L.

Next, as shown in FIG. 1M, a protective layer 123 is formed on the first conductive layer 119 and the second silicon oxide insulator 115, and vias 124 are formed in the protective layer 123 in the pixel area 11. Then, as shown in FIG. 1N, a second conductive layer 125 made of indium tin oxide (ITO) is formed on the protective layer 123 as an ITO conductive layer to completely fill the vias 124. A seventh photoresist 126 is then formed in the pixel area 11. As shown in FIG. 1O, the second conductive layer 125 on the control area 10 is removed using lithography and etching processes, to form a low temperature poly-silicon thin film transistor as shown in FIG. 1O.

As shown in FIG. 1O, the low temperature poly-silicon thin film transistor manufactured by the above-described method comprises: a substrate 100; buffer layers 101, 102 formed on the substrate 100; a poly-silicon layer 104 formed on the buffer layer 102, wherein the poly-silicon layer 104 has a source electrode 104m, a drain electrode 104n, and a channel; first insulators 108, 109 partially formed on the poly-silicon layer 104 to expose the source electrode 104m and the drain electrode 104n of the poly-silicon layer 104; a gate electrode 112 partially formed on the first insulator 109; second insulators 114, 115 partially formed on the gate electrode 112 and partially formed on the first insulator 109; a first conductive layer 119 formed on the source electrode 104m and the drain electrode 104n, wherein a metal film 118 is formed between the first conductive layer 119 and the source electrode 104m and the drain electrode 104n, the first conductive layer 119 reacts with the source electrode 104m and the drain electrode 104n to form a metal silicide layer, and the first conductive layer 119 protrudes above the second insulator 115; a protective layer 123 formed on the first conductive layer 119 and the second insulator 115; and a second conductive layer 125 formed on the protective layer 123 in the pixel area 11.

It should be understood that these examples are merely illustrative of the present invention and the scope of the invention should not be construed to be defined thereby, and the scope of the present invention will be limited only by the appended claims.

What is claimed is:

1. A method for manufacturing a low temperature poly-silicon thin film transistor, comprising:
(A) providing a low temperature poly-silicon thin film transistor substrate, comprising: a substrate; a buffer layer formed on the substrate; a poly-silicon layer formed on the buffer layer, wherein the poly-silicon layer has a source electrode, a drain electrode, and a channel; a first insulator partially formed on the poly-silicon layer, wherein the source electrode and the drain electrode of the poly-silicon layer are exposed therefrom; a gate electrode partially formed on the first insulator; a second insulator partially formed on the gate electrode and partially formed on the first insulator;
(B) forming a metal film on the exposed source electrode and drain electrode in the low temperature poly-silicon thin film transistor substrate;
(C) forming a first conductive layer on the metal film, wherein the first conductive layer protrudes above the second insulator, and performing an annealing process so that the metal film reacts with the source electrode and the drain electrode to form a metal silicide layer; and
(D) forming a protective layer on the first conductive layer and the second insulator to planarize topography of the low temperature poly-silicon thin film transistor.

2. The method of claim 1, wherein, in the step (A), the buffer layer is at least one selected from the group consisting of silicon oxide layer and silicon nitride layer.

3. The method of claim 1, wherein, in the step (A), the first insulator is at least one selected from the group consisting of a silicon oxide layer and a silicon nitride layer.

4. The method of claim 1, wherein, in the step (A), the gate electrode is molybdenum, tungsten or an alloy thereof.

5. The method of claim 1, wherein, in the step (C), the second insulator is at least one selected from the group consisting of a silicon oxide layer and a silicon nitride layer.

6. The method of claim 1, wherein, in the step (B), a material of the metal film is at least one selected from the group consisting of aluminum, nickel, titanium, cobalt, and tungsten.

7. The method of claim 1, wherein, in the step (C), the metal silicide layer is disposed between the metal film and the source and drain electrodes, and the annealing process is controlled at a time period such that a minimum distance between the metal silicide layer at the source electrode and the metal silicide layer at the drain electrode is 2 μm or more.

8. The method of claim 1, wherein, in the step (C), the first conductive layer is composed of molybdenum, molybdenum/aluminum/molybdenum, or titanium/aluminum/titanium.

9. A display device, comprising:
a display panel for displaying an image provided by a low temperature poly-silicon thin film transistor, wherein the low temperature poly-silicon thin film transistor comprises:
a substrate;
a buffer layer formed on the substrate;
a poly-silicon layer formed on the buffer layer, wherein the poly-silicon layer has a source electrode, a drain electrode, and a channel, and the source electrode, the drain electrode, and the channel are doped;
a first insulator partially formed on the poly-silicon layer;
a gate electrode patterned and formed on the first insulator, wherein the gate electrode corresponds to the channel;
a second insulator formed on the gate electrode and the first insulator;
vias passing through the second insulator and the first insulator over the source electrode and the drain electrode respectively;
a metal film formed on the vias over the source electrode and the drain electrode, wherein a metal silicide layer is disposed between the metal film and the source and drain electrodes of the poly-silicon layer;
a first conductive layer formed on the metal film, wherein the first conductive layer protrudes above the second insulator; and
a protective layer formed on the first conductive layer and the second insulator.

10. The display device of claim 9, wherein the substrate is a glass substrate or a plastic substrate.

11. The display device of claim 9, wherein the buffer layer is at least one selected from the group consisting of silicon oxide layer and silicon nitride layer.

12. The display device of claim 9, wherein the first insulator is at least one selected from the group consisting of a silicon oxide layer and a silicon nitride layer.

13. The display device of claim 9, wherein the gate electrode is molybdenum, tungsten or an alloy thereof.

14. The display device of claim 9, wherein the second insulator is at least one selected from the group consisting of a silicon oxide layer and a silicon nitride layer.

15. The display device of claim 9, wherein a minimum distance between the metal silicide layer at the source electrode and the metal silicide layer at the drain electrode is 2 μm or more.

16. The display device of claim 9, wherein the metal silicide layer is formed by a reaction between at least one selected from the group consisting of aluminum, nickel, titanium, cobalt, and tungsten and the source and drain electrodes.

17. The display device of claim 9, wherein a distance between the metal silicide layers is 2 μm or more.

18. The display device of claim 9, wherein the first conductive layer is composed of molybdenum, molybdenum/aluminum/molybdenum, or titanium/aluminum/titanium.
